(19) United States
(12) Patent Application Publication
(10) Pub. No.: US 2026/0239614 A1
(43) Pub. Date: Aug. 13, 2026

(54) ANTIFUSE STRUCTURE FOR ONE-TIME PROGRAMMABLE MEMORY CELL

(71) Applicant: SAMSUNG ELECTRONICS CO., LTD., Suwon-si (KR)

(72) Inventors: Beomjin PARK, Halfmoon, NY (US); YoungGook PARK, Wynantskill, NY (US); Gwang-Sik KIM, Clifton Park, NY (US); Jongmin SHIN, Niskayuna, NY (US); Kang-ill SEO, Springfield, VA (US)

(73) Assignee: SAMSUNG ELECTRONICS CO., LTD., Suwon-si (KR)

(21) Appl. No.: 19/303,980

(22) Filed: Aug. 19, 2025

Related U.S. Application Data
(60) Provisional application No. 63/757,147, filed on Feb. 11, 2025.

(51) Int. Cl. H10B 20/25

(52) U.S. Cl. CPC H10B 20/25

(57) ABSTRACT

A semiconductor device includes a transistor, a storage, a 1^{st} metal line, a 2^{nd} metal line adjacent to the 1^{st} metal line, an air gap between the 1^{st} metal line and the 2^{nd} metal line, and an isolation structure adjacent to the air gap, wherein the 1^{st} metal line is connected to the transistor and the 2^{nd} metal line is connected to the storage.

### CROSS-REFERENCE TO THE RELATED APPLICATION

This application is based on and claims priority from U.S. Provisional Application No. 63/757,147 filed on Feb. 11, 2025 in the U.S. Patent and Trademark Office, the disclosure of which is incorporated herein in its entirety by reference.

### BACKGROUND

### 1. Field

The disclosure relates to a semiconductor device including an antifuse formed in an interconnect structure of the semiconductor device.

### 2. Description of the Related Art

An antifuse for a one-time programmable (OTP) memory cell may be formed to program and read data in a storage of the OTP memory cell using a breakdown voltage applied to a field-effect transistor forming the OTP memory cell. As demand for high-density integrated circuits increases, existing antifuse structures may not satisfy the design requirements for the high-density integrated circuits.

Information disclosed in this Background section has already been known to the inventors before achieving the embodiments of the present application or is technical information acquired in the process of achieving the embodiments. Therefore, it may contain information that does not form the prior art that is already known to the public.

### SUMMARY

The disclosure provides a semiconductor device including an OTP memory cell in which an antifuse structure is formed using metal lines isolated by an air gap in an interconnect structure of the semiconductor device. Thus, the OTP memory cell provided in the disclosure may be formed in a high-density semiconductor device in which metal lines of an interconnect structure are isolated by an air gap instead of an isolation structure such as a dielectric material.

According to one or more embodiments, there is provided a semiconductor device which may include a transistor, a storage, a 1^{st} metal line, a 2^{nd} metal line adjacent to the 1^{st} metal line, an air gap between the 1^{st} metal line and the 2^{nd} metal line, and an isolation structure adjacent to the air gap, wherein the 1^{st} metal line is connected to the transistor and the 2^{nd} metal line is connected to the storage.

According to one or more embodiments, there is provided a semiconductor device which may include a 1^{st} metal line, a 2^{nd} metal line adjacent to the 1^{st} metal line, an air gap between the 1^{st} metal line and the 2^{nd} metal line, and an isolation structure adjacent to the air gap, the isolation structure comprising an isolation material, wherein the 1^{st} metal line and the 2^{nd} metal line are configured to be electrically connected through the isolation structure based on a voltage applied to at least one of the 1^{st} metal line or the 2^{nd} metal line.

According to one or more embodiments, there is provided a semiconductor device which may include a transistor, a storage, and an interconnect structure connected to the transistor and the storage, the interconnect structure including a plurality of 1^{st} metal lines in a 1^{st} area of the interconnect structure, an air gap between two 1^{st} metal lines adjacent to each other among the plurality of 1^{st} metal lines, a plurality of 2^{nd} metal lines in a 2^{nd} area of the interconnect structure, and an isolation structure between two 2^{nd} metal lines adjacent to each other among the plurality of 2^{nd} metal lines, wherein a 2^{nd} metal line among the two 2^{nd} metal lines has a greater width than a 1^{st} metal line among the two 1^{st} metal lines.

### BRIEF DESCRIPTION OF THE DRAWINGS

Example embodiments of the disclosure will be more clearly understood from the following detailed description taken in conjunction with the accompanying drawings, in which:

FIG. 1 illustrates a circuit schematic of an OTP memory cell including an antifuse structure, according to one or more embodiments;

FIGS. 2A and 2B illustrate an interconnect structure in which an antifuse structure including an isolation structure is formed for an OTP memory cell, according to one or more embodiments;

FIGS. 3A and 3B illustrate an interconnect structure in which an antifuse structure including an air gap and an isolation structure is formed for an OTP memory, according to one or more embodiments;

FIGS. 4A-4C illustrate an interconnect structure in which an antifuse structure including an air gap, an isolation structure and a line via structure is formed for an OTP memory, according to one or more embodiments;

FIGS. 5A-5C illustrate an interconnect structure in which an antifuse structure including an air gap, an isolation structure and pillar-type via structures is formed for an OTP memory, according to one or more embodiments;

FIGS. 6A and 6B illustrate an interconnect structure having two different metal pitches, in which an antifuse structure including an isolation structure is formed for an OTP memory, according to one or more embodiments;

FIGS. 7A-7C illustrate an interconnect structure having two different metal pitches, in which an antifuse structure including an isolation structure and a line via structure is formed for an OTP memory, according to one or more embodiments;

FIGS. 8A-8C illustrate an interconnect structure having two different metal pitches, in which an antifuse structure including an isolation structure and pillar-type via structures is formed for an OTP memory, according to one or more embodiments; and

FIG. 9 is a schematic block diagram illustrating an electronic device including one or more semiconductor devices in which one or more OTP memory cells, each including an antifuse structure, are formed, according to one or more embodiments.

### DETAILED DESCRIPTION

All of the embodiments of the disclosure described herein are example embodiments, and thus, the disclosure is not limited thereto, and may be realized in various other forms. Each of the embodiments provided in the following description is not excluded from being associated with one or more features of another example or another embodiment also provided herein or not provided herein but consistent with the disclosure. For example, even if matters described in a specific example or embodiment are not described in a different example or embodiment thereto, the matters may be understood as being related to or combined with the different example or embodiment, unless otherwise mentioned in descriptions thereof. In addition, it should be understood that all descriptions of principles, aspects, examples, and embodiments of the disclosure are intended to encompass structural and functional equivalents thereof. In addition, these equivalents should be understood as including not only currently well-known equivalents but also equivalents to be developed in the future, that is, all devices invented to perform the same functions regardless of the structures thereof. For example, channel layers, sacrificial layers, and isolation layers described herein may take a different type or form as long as the disclosure can be applied thereto.

It will be understood that when an element, component, layer, pattern, structure, region, or so on (hereinafter collectively “element”) of a semiconductor device is referred to as being “over,” “above,” “on,” “below,” “under,” “beneath,” “connected to” or “coupled to” another element of the semiconductor device, it can be directly over, above, on, below, under, beneath, connected or coupled to the other element or an intervening element(s) may be present. In contrast, when an element of a semiconductor device is referred to as being “directly over,” “directly above,” “directly on,” “directly below,” “directly under,” “directly beneath,” “directly connected to” or “directly coupled to” another element of the semiconductor device, there are no intervening elements present. Like numerals refer to like elements throughout this disclosure.

Spatially relative terms, such as “over,” “above,” “on,” “upper,” “below,” “under,” “beneath,” “lower,” “left,” “right,” “lower-left,” “lower-right,” “upper-left,” “upper-right,” “central,” “middle,” and the like, may be used herein for ease of description to describe one element's relationship to another element(s) as illustrated in the figures. It will be understood that the spatially relative terms are intended to encompass different orientations of a semiconductor device in use or operation in addition to the orientation depicted in the figures. For example, if the semiconductor device in the figures is turned over, an element described as “below” or “beneath” another element would then be oriented “above” the other element. Thus, the term “below” can encompass both an orientation of above and below. The semiconductor device may be otherwise oriented (rotated 90 degrees or at other orientations) and the spatially relative descriptors used herein interpreted accordingly. As another example, when elements referred to as a “left” element and a “right” element may be a “right” element and a “left” element when a device or structure including these elements is differently oriented.

It will be understood that, although the terms “1^{st},” “2^{nd},” “3^{rd},” “4^{th},” “5^{th},” “6^{th},” etc. may be used herein to describe various elements, these elements should not be limited by these terms. These terms are only used to distinguish one element from another element. Thus, a 1^{st} element described in the descriptions of the embodiments could be termed a 2^{nd} element in the descriptions of another element or one or more claims, and vice versa without departing from the teachings of the disclosure.

As used herein, expressions such as “at least one of,” when preceding a list of elements, modify the entire list of elements and do not modify the individual elements of the list. For example, the expression, “at least one of a, b and c” and “at least one of a, b or c” should be understood as including only a, only b, only c, both a and b, both a and c, both b and c, or all of a, b and c.

Herein, the terms of degree including “substantially” or “about” may be used. In one or more examples, when specifying that a parameter X may be substantially the same as parameter Y, the term “substantially” may be understood as X being within 10% of Y. In one or more examples, when specifying that a parameter is about X, the term “about” may be understood as being within 10% of X. Still, when a term “same” is used to compare parameters of two or more elements, the term may cover “substantially same” parameters.

It will be understood that, when the term “contact” is used to describe two metal elements, for example, a metal line and a via structure, a barrier metal layer such including titanium (Ti), tantalum (Ta), titanium nitride (TiN), tantalum nitride (TaN), tungsten nitride (WN), nickel nitride (NiN), cobalt nitride (CoN), or platinum nitride (PtN), not being limited thereto, may be formed therebetween. Further, it will be understood that, when a metal contact structure is described as being formed on or contact a surface of a source/drain region, a silicide layer including cobalt silicide (CoSi₂), nickel silicide (NiSi₂), titanium silicide (TiSi₂), or tungsten silicide (WSi₂), not being limited thereto, may be formed therebetween.

It will be also understood that, even if a certain step or operation of manufacturing an apparatus or structure is described later than another step or operation, the step or operation may be performed later than the other step or operation unless the other step or operation is described as being performed after the step or operation.

Many embodiments are described herein with reference to cross-sectional views that are schematic illustrations of the embodiments (and intermediate structures). As such, variations from the shapes of the illustrations as a result, for example, of manufacturing techniques and/or tolerances, are to be expected. Thus, the embodiments should not be construed as limited to the particular shapes of regions illustrated herein but are to include deviations in shapes that result, for example, from manufacturing. Various regions illustrated in the figures are schematic in nature and their shapes are not intended to illustrate the actual shape of a region of a device and are not intended to limit the scope of the disclosure. Further, in the drawings, the sizes and relative sizes of layers and regions may be exaggerated for clarity.

For the sake of brevity, conventional elements, structures or layers of semiconductor devices including a nanosheet transistor and materials forming the same may or may not be described in detail herein. For example, a certain isolation layer or structure of a semiconductor device and materials forming the same may be omitted herein when this layer or structure is not related to the novel features of the embodiments. Also, descriptions of materials forming well-known structural elements of a semiconductor device may be omitted herein when those materials are not relevant to the novel features of the embodiments. Herein, the term “isolation” and “insulation” pertains to electrical insulation or separation between structures, layers, components or regions in a corresponding device or structure.

Performance and power of a fin field-effect transistor (FinFET) and a standard cell formed of FinFETs may be optimized by adjusting the number of fin structures forming a channel structure of each of the FinFETs. As technology advances to a nanosheet transistor, also referred to as a gate-all-around field-effect transistor (GAAFET), performance and power optimization may be achieved by adjusting channel widths of nanosheet layers forming a channel structure of the nanosheet transistor as the nanosheet transistor allows for more flexible width adjustment, and a standard cell with various channel widths offers advantages in implementing therein various different transistor structures satisfying diverse design requirements.

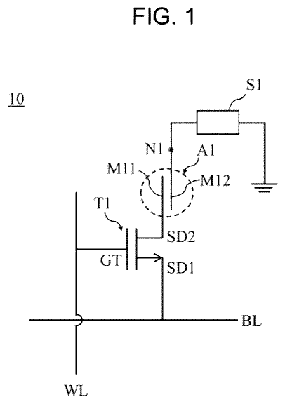

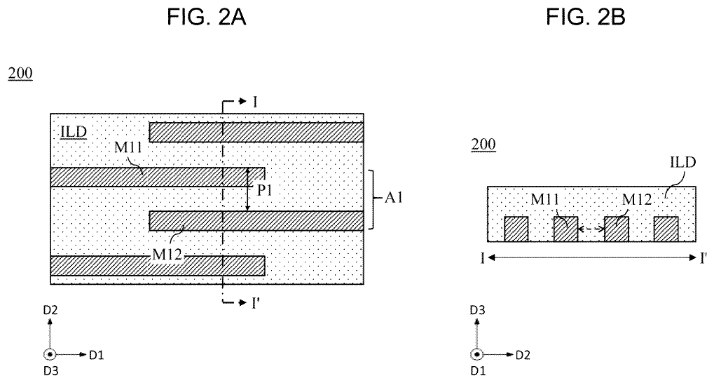

FIG. 1 illustrates a circuit schematic of an OTP memory cell including an antifuse structure, according to one or more embodiments. FIGS. 2A and 2B illustrate an interconnect structure in which an antifuse structure including an isolation structure is formed for an OTP memory cell, according to one or more embodiments. FIG. 2A is a plan view of the interconnect structure including the antifuse structure, and FIG. 2B is a cross-section view of the interconnect structure of FIG. 2A taken along a line I-I′ shown in FIG. 2A, according to one or more embodiments.

Referring to FIG. 1, an OTP memory cell 10 may include a field-effect transistor T1 as an access transistor and a storage S1 controlled by the field-effect transistor T1 through a storage node N1. The storage S1 may be formed of, for example, a capacitor when the OTP memory cell 10 is a dynamic random-access memory (DRAM) cell. However, the disclosure is not limited thereto. According to one or more other embodiments, the storage S2 may be formed of one or more transistors to form a latch structure or a floating gate structure to form the OTP memory cell 10 as a static random-access memory (SRAM) cell or a flash memory cell.

The field-effect transistor T1 may be connected to a word line WL and a bit line BL through a gate GT and a 1^{st} source/drain SD1 region thereof, respectively. Further, a 2^{nd} source/drain region SD2 of the field-effect transistor T1 may be connected to the storage S1 through an antifuse A1 which is formed of a 1^{st} metal line M11 connected to the 2^{nd} source/drain region SD2 and a 2^{nd} metal line M12 connected to the storage S1 through the storage node N1.

Referring to FIGS. 2A and 2B along with FIG. 1, the 1^{st} metal line M11 and the 2^{nd} metal line M12 forming the antifuse A1 may be two adjacent metal lines among a plurality of metal lines included in an interconnect structure 200 formed in a back-end-of-line (BEOL) process of manufacturing a semiconductor device including the OTP memory cell 10. The plurality of metal lines including the metal lines M11 and M12 may extend in a 1^{st} direction D1, may be arranged in a 2^{nd} direction D2 at a predetermined metal pitch P1, and may be formed at a same metal layer, for example, M1 layer, or at a same level above the field-effect transistor T1 in a 3^{rd} direction D3. Herein, the 1^{st} direction D1 and the 2^{nd} direction D2 may be horizontal directions intersecting each other, and the 3^{rd} direction D3 may be a vertical direction intersecting the horizontal directions.

To form the antifuse A1, an isolation structure ILD formed of an isolation or insulation material such as a low-k dielectric material, for example, an oxide material or silicon oxide (SiO₂), may be formed between the two metal lines M11 and M12 arranged in the 2^{nd} direction D2. A material forming the metal lines M11 and M12 may be, for example, copper (Cu), tungsten (W), cobalt (Co), etc. which may be formed in the isolation structure ILD through a damascene process. A barrier metal layer may be formed between each of the metal lines M11 and M12 and the isolation structure ILD to prevent metal atoms from being diffused into the isolation structure ILD. For example, a material forming the barrier metal layer may be titanium (Ti), titanium nitride (TiN), tantalum (Ta), tantalum nitride (TaN), etc.

The OTP memory cell 10 including the antifuse A1 may be programmed when the gate GT is turned on to apply a voltage from the bit line BL to the 1^{st} source/drain region SD1 so that a portion of the isolation structure ILD between the two metal lines M11 and M12 is broken down to allow current leakage to the portion of the isolation structure ILD, thereby electrically connecting the 1^{st} metal line M11 and the 2^{nd} metal line M12 through the broken-down portion of the isolation structure ILD as indicated by a dashed line in FIG. 2B. The OTP memory cell 10 including the antifuse A1 may be read also by controlling breakdown of the isolation structure between the two metal lines M11 and M12 by applying a voltage from the bit line BL to the 1^{st} source/drain region SD1 and turning on the gate GT.

However, the antifuse A1 may not function when the isolation structure ILD is not formed between the two metal lines M11 and M12, for example, when an air gap is formed between the two metal lines M11 and M12. Thus, the following embodiments provide interconnect structures in which two adjacent metal lines without an isolation structure therebetween may still form an antifuse structure for an OTP memory.

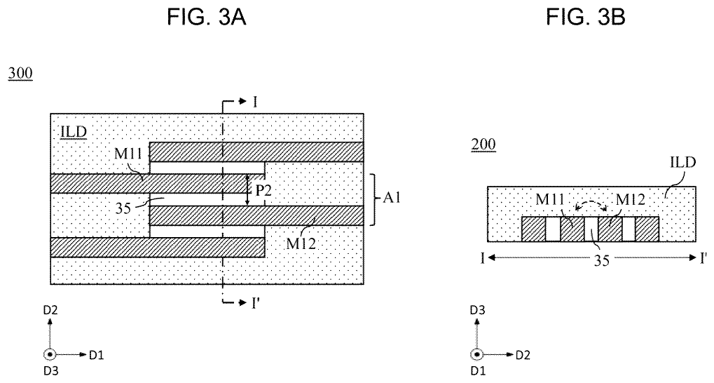

FIGS. 3A and 3B illustrate an interconnect structure in which an antifuse structure including an air gap and an isolation structure is formed for an OTP memory, according to one or more embodiments. FIG. 3A is a plan view of the interconnect structure including the antifuse structure, and FIG. 3B is a cross-section view of the interconnect structure of FIG. 3A taken along a line I-I′ shown in FIG. 3A, according to one or more embodiments.

Referring to FIGS. 3A and 3B, an interconnect structure 300, like the interconnect structure 200 of the FIGS. 2A and 2B, may also include a plurality of metal lines including a 1^{st} metal line M11 and a 2^{nd} metal line M12 which form an antifuse A1 for the OTP memory cell 10 of FIG. 1 in place of the antifuse A1 of the interconnect structure 200. Thus, the 1^{st} metal line M11 and the 2^{nd} metal line M12 in the interconnect structure 300 may be respectively connected to the 2^{nd} source/drain region SD2 and the storage S1 of the OTP memory cell 10.

However, the plurality of metal lines in the interconnect structure 300 may have a metal pitch P2 which is smaller than the metal pitch P1 in the interconnect structure 200. Further, a material forming the plurality of metal lines in the interconnect structure 300 may be ruthenium (Ru) which may advantageously enable a smaller-metal-pitch interconnect structure. Ru is known to provide a lower resistance and a reduced electromigration property than other metal materials such as Cu.

The interconnect structure 300 may be formed such that an initial metal structure of Ru is patterned through, for example, dry etching, not being limited thereto, to form the plurality of metal lines extending in the 1^{st} direction D1 and arranged in the 2^{nd} direction D2 at the metal pitch P2. Subsequently, an isolation structure ILD may be formed to surround and isolate the plurality of metal lines to form the interconnect structure 300. However, due to the small metal pitch P2, an isolation material such as a dielectric material (e.g., SiO₂) may not fill in gaps between the plurality of metal lines, and thus, air gaps 35 may be formed between the plurality of metal lines including the metal lines M11 and M12. The air gaps 35 may also form an isolation structure in the interconnect structure 300 to isolate the plurality of metal lines from each other. Further, as the isolation structure ILD is formed after the formation of the plurality of metal lines of Ru which has a low electromigration property unlike the interconnect structure 200 of FIGS. 2A and 2B, a barrier metal layer may not need to be formed between each of the plurality of metal lines and the isolation structure ILD to prevent Ru atoms from being diffused into the isolation structure ILD.

In the meantime, due to the small metal pitch P2, when a programming voltage or a read voltage is applied to the field-effect transistor T1 of the OTP memory cell 10 including the antifuse A1 of the interconnect structure 300, a portion of the isolation structure ILD formed adjacent to, for example, directly above, an air gap 35 between the metal lines M11 and M12 may be broken down to allow current leakage to the portion of the isolation structure ILD, thereby electrically connecting the two metal lines M11 and M12 through the broken-down portion of the isolation structure ILD as indicated by the dashed curve shown in FIG. 3B. Thus, even with the air gap 35 between the metal lines M11 and M12, the metal lines M11 and M12 in the interconnect structure 300 may form the antifuse A1 of the OTP memory cell 10 of FIG. 1.

It is to be understood here that FIG. 3A does not show portions of the isolation structure ILD formed above the air gaps 35 between the plurality of metal lines as shown in FIG. 3B in order to show that the air gaps 35 are formed between the plurality of metal lines including the metal lines M11 and M12 at a same level.

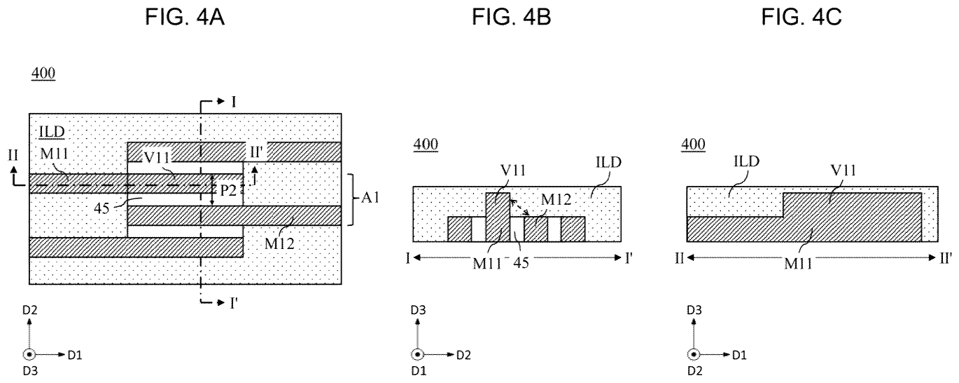

FIGS. 4A-4C illustrate an interconnect structure in which an antifuse structure including an air gap, an isolation structure and a line via structure is formed for an OTP memory, according to one or more embodiments; FIG. 4A is a plan view of the interconnect structure including the antifuse structure, FIG. 4B is a cross-section view of the interconnect structure of FIG. 4A taken along a line I-I′ shown in FIG. 4A, and FIG. 4C is a cross-section view of the interconnect structure of FIG. 4A along a line II-II′ shown in FIG. 4A, according to one or more embodiments.

Referring to FIGS. 4A-4C, an interconnect structure 400, like the interconnect structure 200 of the FIGS. 2A and 2B, may also include a plurality of metal lines including a 1^{st} metal line M11 and a 2^{nd} metal line M12. However, the interconnect structure 400 may be similar to the interconnect structure 300 of FIGS. 3A and 3B in that the plurality of metal lines therein also have the same small metal pitch P2, which is smaller than the metal pitch P1, in the interconnect structure 200 of FIGS. 2A and 2B. Also, a material forming the plurality of metal lines in the interconnect structure 400 may be Ru which may advantageously enable a smaller-metal-pitch interconnect structure like in the interconnect structure 300.

Unlike in the interconnect structure 300, the 1^{st} metal line M11 in the interconnect structure 400 may have a via structure V11 formed thereon. In the interconnect structure 400, this via structure V11 and the 2^{nd} metal line M12 may form an antifuse A1 for the OTP memory cell 10 of FIG. 1 in place of the antifuse A1 of the interconnect structure 200. For example, the via structure V11 may be connected to the 2^{nd} source/drain region SD2 of the field-effect transistor T1 while the 2^{nd} metal line M12 may be connected to the storage S1 through the storage node N1 in the OTP memory cell 10.

The interconnect structure 400 may be formed in a manner which is the same as or similar to that for forming the interconnect structure 300 except that the 1^{st} metal line M11 is formed from the initial metal structure of Ru to be higher than the other metal lines including the 2^{nd} metal line M12, and is further etched at a selected portion to form a protrusion thereon, as shown in FIGS. 4B and 4C, through, for example, dry etching, not being limited thereto. This protrusion formed on the remaining 1^{st} metal line M11 may form and may be referred to as the via structure V11 on the 1^{st} metal line M11. Thus, the 1^{st} metal line M11 and the via structure V11 thereon may form a single continuum metal structure without a connection surface, interface or junction therebetween when viewed through transmission electron microscopy (TEM) or scanning electron microscopy (SEM).

Subsequent to the formation of the plurality of metal lines including the 1^{st} metal line M11, with the via structure V11 thereon, and the 2^{nd} metal line M12, an isolation structure ILD may be formed to surround and isolate the plurality of metal lines to form the interconnect structure 400. Thus, the interconnect structure 400 may also include air gaps 45 between the plurality of metal lines including the metal lines M11 and M12 having the small metal pitch P2. The air gaps 45 may also form an isolation structure in the interconnect structure 400 to isolate the plurality of metal lines from each other.

Like in the interconnect structure 300, when a programming voltage or a read voltage is applied to the field-effect transistor T1 of the OTP memory cell 10 including the antifuse A1 of the interconnect structure 400, a portion of the isolation structure ILD formed adjacent to, for example, directly above, an air gap 45 between the metal lines M11 and M12 may be broken down to allow current leakage to the portion of the isolation structure ILD, thereby electrically connecting the via structure V11 and the 2^{nd} metal line M12 through the broken-down portion of the isolation structure ILD as indicated by the dashed line shown in FIG. 4B. Here, the via structure V11 instead of the 1^{st} metal line M11 may be connected to the 2^{nd} source/drain region SD2 of the field-effect transistor T1 of the OTP memory cell 10 while the 2^{nd} metal line M12 may be connected to the storage S1 through the storage node N1 of the OTP memory cell 10.

Thus, even with the air gap 45 between the metal lines M11 and M12, the via structure V11 and the 2^{nd} metal line M12 in the interconnect structure 400 may form the antifuse A1 of the OTP memory cell 10 of FIG. 1.

In the meantime, the via structure V11 may take a form or shape of a line via structure extending in the 1^{st} direction D1 as shown in FIG. 4A so that a length of the via structure V11 in the 1^{st} direction D1 is greater than a width of the via structure V11 in the 2^{nd} direction D2. The width of the via structure V11 may be equal to a width of the 1^{st} metal line M11 in the 2^{nd} direction D2. Further, the via structure V11 is formed on the 1^{st} metal line M11 at a portion that overlaps the 2^{nd} metal line M12 in the 2^{nd} direction D2. Thus, the extended length of the via structure V11 may increase an electrical connection area between the via structure V11 and the 2^{nd} metal line M12, thereby enhancing antifuse performance.

In the meantime, according to one or more other embodiments, the 2^{nd} metal line M12 may also be formed to have a via structure having the same structural line shape as the via structure V11 on the 1^{st} metal line M11 and entirely or partially overlapping the via structure V11 in the 2^{nd} direction D2. This embodiment may achieve a shorter electrical connection length between the two via structures at a same level for the antifuse A1 than in the interconnect structure 400. In this case, the via structure on the 2^{nd} metal line M12 may be connected to the storage S1 through the storage node N1 while the via structure V11 on the 1^{st} metal line M11 is connected to the 2^{nd} source/drain region SD2 of the field-effect transistor T1 of the OTP memory cell 10.

It is to be understood here that, like in FIG. 3A, FIG. 4A does not show portions of the isolation structure ILD formed above the air gaps 45 between the plurality of metal lines as shown in FIG. 4B in order to show that the air gaps 45 are formed between the plurality of metal lines including the metal lines M11 and M12 at a same level.

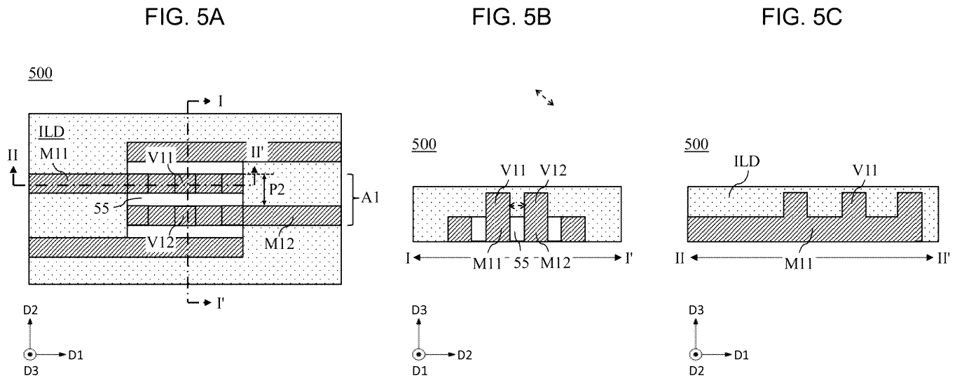

FIGS. 5A-5C illustrate an interconnect structure in which an antifuse structure including an air gap, an isolation structure and pillar-type via structures is formed for an OTP memory, according to one or more embodiments. FIG. 5A is a plan view of the interconnect structure including the antifuse structure, FIG. 5B is a cross-section view of the interconnect structure of FIG. 5A taken along a line I-I′ shown in FIG. 5A, and FIG. 5C is a cross-section view of the interconnect structure of FIG. 5A along a line II-II′ shown in FIG. 5A, according to one or more embodiments.

Referring to FIGS. 5A-5C, an interconnect structure 500, like the interconnect structure 200 of the FIGS. 2A and 2B, may also include a plurality of metal lines including a 1^{st} metal line M11 and a 2^{nd} metal line M12. However, the interconnect structure 500 may be similar to the interconnect structure 400 of FIGS. 4A and 4B in that the plurality of metal lines therein may also have the same small metal pitch P2 which is smaller than the metal pitch P1 in the interconnect structure 200 of FIGS. 2A and 2B. Also, a material forming the plurality of metal lines in the interconnect structure 500 may be Ru which may advantageously enable a smaller-metal-pitch interconnect structure like in the interconnect structure 400.

Unlike in the interconnect structure 400, the 1^{st} metal line M11 in the interconnect structure 400 may have a plurality of 1^{st} via structures including a 1^{st} via structure V11 formed thereon. Further, the 2^{nd} metal line M12 in the interconnect structure 400 may also have a plurality of 2^{nd} via structures including a 2^{nd} via structure V12 formed thereon. The 1^{st} via structures and the 2^{nd} via structures may be formed to face each other in the 2^{nd} direction D2. For example, the 1^{st} via structure V11 and the 2^{nd} via structure V12 may be formed to face each other in the 2^{nd} direction D2. The 1^{st} via structure V11 and the 2^{nd} via structure V12 may form an antifuse A1 for the OTP memory cell 10 of FIG. 1 in place of the antifuse A1 of the interconnect structure 200. For example, the 1^{st} via structure V11 may be connected to the 2^{nd} source/drain region SD2 of the field-effect transistor T1 and the 2^{nd} via structure V12 may be connected to the storage S1 through the storage node N1 in the OTP memory cell 10.

The interconnect structure 500 may be formed in a manner which is the same as or similar to that for forming the interconnect structure 300 of FIGS. 3A and 3B except that the 1^{st} metal line M11 and the 2^{nd} metal line M2 are formed from the initial metal structure of Ru to be higher than the other metal lines, and are further etched at selected portions to form a plurality of protrusions thereon, as shown in FIG. 5C, through, for example, dry etching, not being limited thereto. These protrusions formed on the remaining 1^{st} metal line M11 and the remaining 2^{nd} metal line M12 may each be in a pillar shape having a smaller length than the via structure V11 of the interconnect structure 400 in the 1^{st} direction D1 while they may each have a same width as each of the metal lines M11 and M12 in the 2^{nd} direction D2. In the interconnect structure 500, these short-length protrusions may form and may be referred to as the 1^{st} via structures on the 1^{st} metal line M11 and the 2^{nd} via structures on the 2^{nd} metal line M12, respectively.

Thus, the 1^{st} metal line M11 and the 1^{st} via structures thereon may form a single continuum metal structure without a connection surface, interface or junction therebetween, and the 2^{nd} metal line M12 and the 2^{nd} via structures thereon may also form a single continuum metal structure without a connection surface, interface or junction therebetween, when viewed through TEM or SEM.

Subsequent to the formation of the plurality of metal lines including the 1^{st} metal line M11 with the plurality of 1^{st} via structures thereon and the 2^{nd} metal line M12 with the plurality of 2^{nd} via structures thereon, an isolation structure ILD may be formed to surround and isolate these metal structures to form the interconnect structure 500. Thus, the interconnect structure 500 may also include air gaps 55 between the plurality of metal lines including the metal lines M11 and M12 having the small metal pitch P2. The air gaps 55 may also form an isolation structure in the interconnect structure 500 to isolate the plurality of metal lines from each other.

Like in the interconnect structure 300, when a programming voltage or a read voltage is applied to the field-effect transistor T1 of the OTP memory cell 10 including the antifuse A1 of the interconnect structure 500, a portion of the isolation structure ILD adjacent to, for example, directly above, an air gap 45 between the via structures V11 and V12 may be broken down to allow current leakage to the portion of the isolation structure ILD, thereby electrically connecting the 1^{st} via structure V11 and the 2^{nd} via structure V12 through the broken-down portion of the isolation structure ILD as indicated by the dashed line shown in FIG. 5B. Here, the 1^{st} via structure V11 instead of the 1^{st} metal line M11 may be connected to the 2^{nd} source/drain region SD2 of the field-effect transistor T1 of the OTP memory cell 10, and the 2^{nd} via structure V12 instead of the 2^{nd} metal line M12 may be connected to the storage S1 through the storage node N1 of the OTP memory cell 10.

Thus, even with the air gap 55 between the metal lines M11 and M12, the 1^{st} via structure V11 and the 2^{nd} via structure V12 in the interconnect structure 500 may form the antifuse A1 of the OTP memory cell 10 of FIG. 1.

In the meantime, according to one or more other embodiments, the 2^{nd} via structures may not be formed on the 2^{nd} metal line M12 while the 1^{st} via structures are formed on the 1^{st} metal line M11, in which case, the 2^{nd} metal line M12 and the 1^{st} via structure V11 may form the antifuse A1 of the OTP memory cell 10 of FIG. 1 in place of the antifuse A1 in the interconnect structure 500.

It is to be understood here that, like FIG. 4A, FIG. 5A does not show portions of the isolation structure ILD formed above the air gaps 55 between the plurality of metal lines as shown in FIG. 5B in order to show that the air gaps 55 are formed between the plurality of metal lines including the metal lines M11 and M12 at a same level.

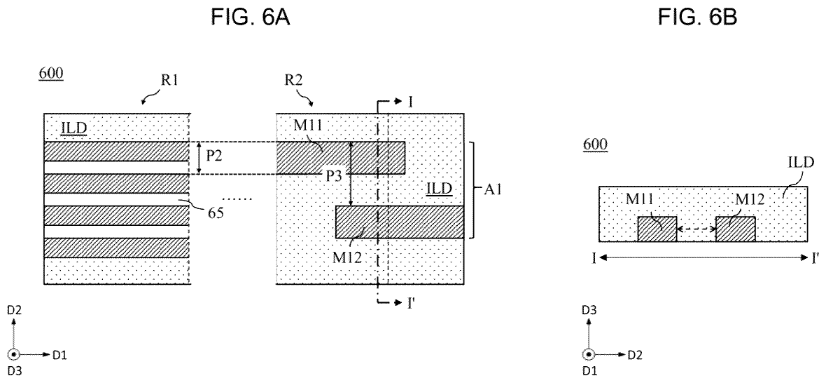

FIGS. 6A and 6B illustrate an interconnect structure having two different metal pitches, in which an antifuse structure including an isolation structure is formed for an OTP memory, according to one or more embodiments. FIG. 6A is a plan view of the interconnect structure including the antifuse structure, and FIG. 6B is a cross-section view of the interconnect structure of FIG. 6A taken along a line I-I′ shown in FIG. 6A, according to one or more embodiments.

Referring to FIGS. 6A and 6B, an interconnect structure 600, like the interconnect structure 200 of the FIGS. 2A and 2B, may also include a plurality of metal lines including a 1^{st} metal line M11 and a 2^{nd} metal line M12 which form an antifuse A1 for the OTP memory cell 10 of FIG. 1 in place of the antifuse A1 of the interconnect structure 200. Thus, the 1^{st} metal line M11 and the 2^{nd} metal line M12 in the interconnect structure 600 may be respectively connected to the 2^{nd} source/drain region SD2 and the storage S1 of the OTP memory cell 10.

Like in the interconnect structure 500, the plurality of metal lines in the interconnect structure 600 may be formed of Ru. However, the interconnect structure 600 may be formed through, for example, dry etching of an initial metal structure of Ru to have two different metal pitches P2 and P3 for the plurality of metal lines in a 1^{st} area R1 and a 2^{nd} area R2, respectively. For example, in the 1^{st} area R1, the plurality of metal lines may be formed to have a metal pitch P2 preventing formation of an isolation structure ILD therebetween and instead allowing formation of air gaps 65 therebetween. In contrast, in the 2^{nd} area R2, the 1^{st} metal line M11 and the 2^{nd} metal line M12 may be formed to have an extended width in the 2^{nd} direction D2 and arranged at an extended metal pitch P3, which is greater than the metal pitch P2, thereby allowing formation of the isolation structure ILD therebetween instead of the air gap 65. The width of each of the metal lines M11 and M12 in the 2^{nd} area R2 may be equal to the metal pitch P2 of the metal lines in the 1^{st} area R1, which may also be equal to a sum of a width of each metal line and a width of the air gap 65 in the 2^{nd} direction D2 in the 1^{st} area.

As the two metal lines M11 and M12 have the extended metal pitch P3 as well as the extended width, the isolation structure ILD may be formed therebetween instead of an air gap. Like in the isolation structure 200, the 1^{st} metal line M11 may be connected to the 2^{nd} source/drain region SD2 of the field-effect transistor T1 and the 2^{nd} metal line M12 may be connected to the storage S1 through the storage node N1 to form the antifuse A1 of the OTP memory cell 10 of FIG. 1.

When a programming voltage or a read voltage is applied to the field-effect transistor T1 of the OTP memory cell 10 including the antifuse A1 of the interconnect structure 600, a portion of the isolation structure ILD between the metal lines M11 and M12 may be broken down to allow current leakage to the portion of the isolation structure ILD, thereby electrically connecting the two metal lines M11 and M12 through the broken-down portion of the isolation structure ILD as indicated by the dashed line shown in FIG. 6B. Thus, even with the air gaps 65 formed between the plurality of metal lines, the metal lines M11 and M12 in the interconnect structure 300 along with a portion of the isolation structure ILD therebetween may form the antifuse A1 of the OTP memory cell 10 of FIG. 1.

It is to be understood here that, like FIG. 5A, FIG. 6A does not show portions of the isolation structure ILD formed above the air gaps 65 between the plurality of metal lines in order to show that the air gaps 65 are formed between the plurality of metal lines at a same level.

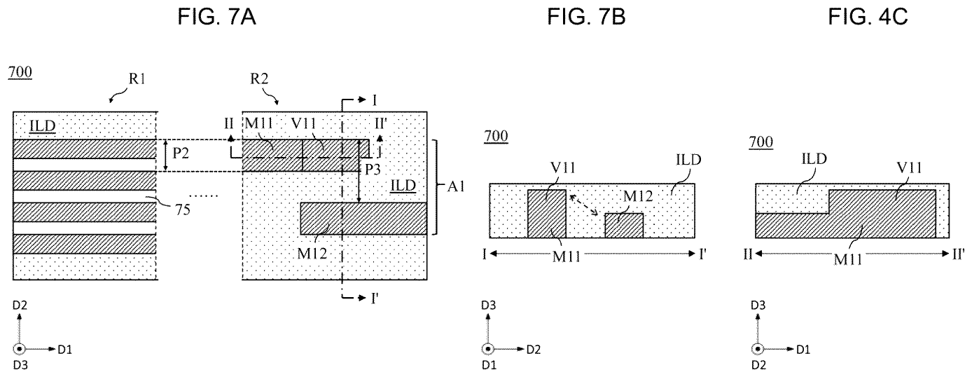

FIGS. 7A-7C illustrate an interconnect structure having two different metal pitches, in which an antifuse structure including an isolation structure and a line via structure is formed for an OTP memory, according to one or more embodiments. FIG. 7A is a plan view of the interconnect structure including the antifuse structure, FIG. 7B is a cross-section view of the interconnect structure of FIG. 7A taken along a line I-I′ shown in FIG. 7A, and FIG. 7C is a cross-section view of the interconnect structure of FIG. 7A along a line II-II′ shown in FIG. 7A, according to one or more embodiments.

Referring to FIGS. 7A-7C, an interconnect structure 700, like the interconnect structure 600 of the FIGS. 6A and 6B, may also include a plurality of metal lines of Ru including a 1^{st} metal line M11 and a 2^{nd} metal line M12 that have two different metal pitches P2 and P3 in a 1^{st} area R1 and a 2^{nd} area R2, respectively. Thus, duplicate descriptions thereof including formation of air gaps 75 and an isolation structure ILD in the respective areas R1 and R2 may be omitted herein.

However, unlike in the interconnect structure 600, the 1^{st} metal line M11 in the interconnect structure 700 may have a via structure V11 formed thereon. Similar to the via structure V11 in the interconnect structure 400 of FIGS. 4A-4C, the via structure V11 in the interconnect structure 700 may also take a form of protrusion and a line via structure formed on a portion of the 1^{st} metal line M11 that overlaps the 2^{nd} metal line M12 in the 2^{nd} direction D2. Further, the via structure V11 and the 1^{st} metal line M11 may form a single continuum metal structure without a connection surface, interface or junction therebetween, when viewed through TEM or SEM. Thus, in the interconnect structure 700, the via structure V11 and the 2^{nd} metal line M12 may form an antifuse A1 for the OTP memory cell 10 of FIG. 1 in place of the antifuse A1 of the interconnect structure 200. For example, the via structure V11 may be connected to the 2^{nd} source/drain region SD2 of the field-effect transistor T1 while the 2^{nd} metal line M12 may be connected to the storage S1 through the storage node N1 in the OTP memory cell 10.

When a programming voltage or a read voltage is applied to the field-effect transistor T1 of the OTP memory cell 10 including the antifuse A1 of the interconnect structure 700, a portion of the isolation structure ILD between the via structure V11 and the 2^{nd} metal line M12 may be broken down to allow current leakage to the portion of the isolation structure ILD, thereby electrically connecting the via structure V11 and the 2^{nd} metal line M12 through the broken-down portion of the isolation structure ILD as indicated by the dashed line shown in FIG. 7B. Thus, even with the air gaps 75 formed between the plurality of metal lines, the 1^{st} via structure V11 and the 2^{nd} metal structure M12 in the interconnect structure 700 along with a portion of the isolation structure ILD therebetween may form the antifuse A1 of the OTP memory cell 10 of FIG. 1.

Like in the interconnect structure 400 of FIGS. 4A-4C, the extended length of the via structure V11 in the interconnect structure 700 may increase an electrical connection area between the via structure V11 and the 2^{nd} metal line M12, thereby enhancing antifuse performance.

In the meantime, according to one or more other embodiments, the 2^{nd} metal line M12 may also be formed to have a via structure having the same structural line shape as the via structure V11 on the 1^{st} metal line M11 and entirely or partially overlapping the via structure V11 in the 2^{nd} direction D2. This embodiment may achieve a shorter electrical connection length between the two via structures at a same level for the antifuse A1 than in the interconnect structure 700. In this case, the via structure on the 2^{nd} metal line M12 may be connected to the storage S1 through the storage node N1 while the via structure V11 on the 1^{st} metal line M11 is connected to the 2^{nd} source/drain region SD2 of the field-effect transistor T1 of the OTP memory cell 10.

It is to be understood here that, like FIG. 6A, FIG. 7A does not show portions of the isolation structure ILD formed above the air gaps 75 between the plurality of metal lines in order to show that the air gaps 75 are formed between the plurality of metal lines at a same level.

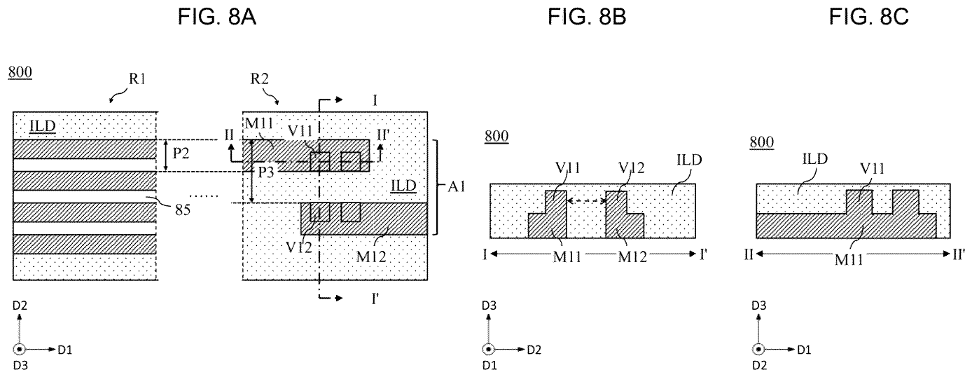

FIGS. 8A-8C illustrate an interconnect structure having two different metal pitches, in which an antifuse structure including an isolation structure and pillar-type via structures is formed for an OTP memory, according to one or more embodiments. FIG. 8A is a plan view of the interconnect structure including the antifuse structure, FIG. 8B is a cross-section view of the interconnect structure of FIG. 8A taken along a line I-I′ shown in FIG. 8A, and FIG. 8C is a cross-section view of the interconnect structure of FIG. 8A along a line II-II′ shown in FIG. 8A, according to one or more embodiments.

Referring to FIGS. 8A-8C, an interconnect structure 800, like the interconnect structure 700 of the FIGS. 7A-7C, may also include a plurality of metal lines of Ru including a 1^{st} metal line M11 and a 2^{nd} metal line M12 that have two different metal pitches P2 and P3 in a 1^{st} area R1 and a 2^{nd} area R2, respectively. Thus, duplicate descriptions thereof including formation of air gaps 85 and an isolation structure ILD in the respective areas R1 and R2 may be omitted herein.

However, unlike in the interconnect structure 700, the 1^{st} metal line M11 in the interconnect structure 800 may have a plurality of 1^{st} via structures including a 1^{st} via structure V11 formed thereon. Further, the 2^{nd} metal line M12 in the interconnect structure 400 may also have a plurality of 2^{nd} via structures including a 2^{nd} via structure V12 formed thereon. Thus, the 1^{st} via structure V11 and the 2^{nd} via structure V12 may form an antifuse A1 for the OTP memory cell 10 of FIG. 1 in place of the antifuse A1 of the interconnect structure 200. For example, the 1^{st} via structure V11 may be connected to the 2^{nd} source/drain region SD2 of the field-effect transistor T1 and the 2^{nd} via structure V12 may be connected to the storage S1 through the storage node N1 in the OTP memory cell 10.

The formation of the 1^{st} via structures and the 2^{nd} via structures respectively on the 1^{st} metal lines M11 and the 2^{nd} metal line M12 may be performed in a manner similar to those in the interconnect structure 500 shown in FIGS. 5A-5C. However, unlike in the interconnect structure 500, the 1^{st} via structures and the 2^{nd} via structures in the interconnect structure 800 may each be formed to have a shorter width than each of the metal lines M11 and M12 in the 2^{nd} direction D2 as well as a shorter length than the via structure V11 in the interconnect structure 700 in the 1^{st} direction D1. Further, the 1^{st} via structures may be formed at respective positions on the 1^{st} metal line M11 close to the 2^{nd} metal line M12, and the 2^{nd} via structures may be formed at respective positions on the 2^{nd} metal line M12 close to the 1^{st} metal line M11 to shorten an electrical connection distance therebetween.

Still, however, the 1^{st} via structure V11 and the 2^{nd} via structure V1 may be formed to face each other in the 2^{nd} direction D2 as in the interconnect structure 500. Also, the 1^{st} metal line M11 and the 1^{st} via structures thereon may form a single continuum metal structure without a connection surface, interface or junction therebetween, and the 2^{nd} metal line M12 and the 2^{nd} via structures thereon may also form a single continuum metal structure without a connection surface, interface or junction therebetween, when viewed through TEM or SEM.

When a programming voltage or a read voltage is applied to the field-effect transistor T1 of the OTP memory cell 10 including the antifuse A1 of the interconnect structure 800, a portion of the isolation structure ILD between the 1^{st} via structures and the 2^{nd} via structure V12 may be broken down to allow current leakage to the portion of the isolation structure ILD, thereby electrically connecting the two via structure V11 and V12 through the broken-down portion of the isolation structure ILD as indicated by the dashed line shown in FIG. 8B. Here, the 1^{st} via structure V11 may be connected to the 2^{nd} source/drain region SD2 of the field-effect transistor T1 of the OTP memory cell 10, and the 2^{nd} via structure V12 may be connected to the storage S1 through the storage node N1 of the OTP memory cell 10.

In the meantime, according to one or more other embodiments, the 2^{nd} via structures may not be formed on the 2^{nd} metal line M12 while the 1^{st} via structures are formed on the 1^{st} metal line M11, in which case, the 2^{nd} metal line M12 and the 1^{st} via structure V11 may form the antifuse A1 of the OTP memory cell 10 of FIG. 1 in place of the antifuse A1 in the interconnect structure 800.

It is to be understood here that, like FIG. 7A, FIG. 8A does not show portions of the isolation structure ILD formed above the air gaps 85 between the plurality of metal lines in order to show that the air gaps 85 are formed between the plurality of metal lines at a same level.

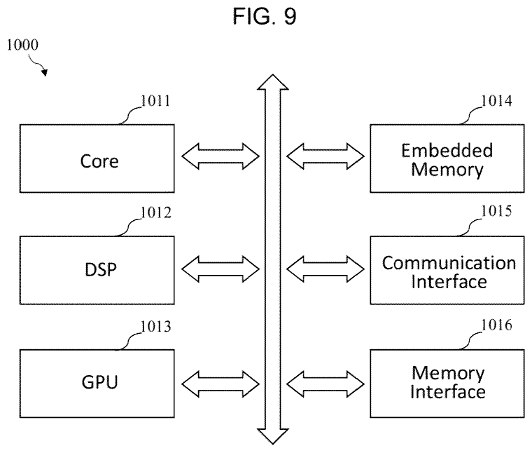

FIG. 9 is a schematic block diagram illustrating an electronic device including one or more semiconductor devices in which one or more OTP memory cells, each including an antifuse structure, are formed, according to one or more embodiments. The antifuse structures included in the OTP memory cells may be implemented by at least one of the antifuse structures described above in reference to FIGS. 2A-2B to 8A-8C.

Referring to FIG. 9, an SoC 1000 may be an integrated circuit in which components of a computing system or other electronic systems are integrated. As an example of the SoC 1000, an application processor (AP) may include at least one processor and components for various functions. The SoC 1000 may include a core 1011 (e.g., a processor), a digital signal processor (DSP) 1012, a graphic processing unit (GPU) 1013, an embedded memory 1014, a communication interface 1015, and a memory interface 1016. The components of the SoC 1000 may communicate with each other through a bus 1007.

The core 1011 may process instructions and control operations of the components included in the SoC 1000. For example, the core 1011 may process a series of instructions to run an operating system and execute applications on the operating system. The DSP 1012 may generate useful data by processing digital signals (e.g., a digital signal provided from the communication interface 1015). The GPU 1013 may generate data for an image output by a display device from image data provided from the embedded memory 1014 or the memory interface 1016, or may encode the image data.

The embedded memory 1014 may store data necessary for the core 1011, the DSP 1012, and the GPU 1013 to operate. The communication interface 1015 may provide an interface for a communication network or one-to-one communication. The memory interface 1016 may provide an interface for an external memory of the SoC 1000, such as a dynamic random access memory (DRAM), a flash memory, etc.

At least one of the core 1011, the DSP 1012, the GPU 1013, or the embedded memory 1014 may include at least one of the antifuse structures described above in reference to FIGS. 2A-2B to 8A-8C.

The foregoing is illustrative of example embodiments and is not to be construed as limiting the disclosure. Although a few example embodiments have been described, those skilled in the art will readily appreciate that many modifications are possible in the above embodiments without materially departing from the disclosure.

What is claimed is:

1. A semiconductor device comprising:
a transistor;
a storage;
a 1^{st} metal line;
a 2^{nd} metal line adjacent to the 1^{st} metal line;
an air gap between the 1^{st} metal line and the 2^{nd} metal line; and
an isolation structure adjacent to the air gap, and
wherein the 1^{st} metal line is connected to the transistor, and the 2^{nd} metal line is connected to the storage.

2. The semiconductor device of claim 1, wherein, based on a voltage applied to at least one of the 1^{st} metal line or the 2^{nd} metal line, the at least one of the 1^{st} metal line or the 2^{nd} metal line is configured to generate current leakage into the isolation structure, and the 1^{st} metal line and the 2^{nd} metal line are configured to be electrically connected through the isolation structure.

3. The semiconductor device of claim 1, further comprising a via structure on the 1^{st} metal line or the 2^{nd} metal line,
wherein, based on the via structure being on the 1^{st} metal line, the 1^{st} metal line is connected to the transistor through the via structure, and
wherein, based on the via structure being on the 2^{nd} metal line, the 2^{nd} metal line is connected to the storage through the via structure.

4. The semiconductor device of claim 3, wherein, based on a voltage applied to at least one of the 1^{st} metal line or the 2^{nd} metal line, the via structure is configured to generate current leakage into the isolation structure, and the via structure and the 1^{st} metal line or the 2^{nd} metal line are configured to be electrically connected through the isolation structure.

5. The semiconductor device of claim 3, the via structure and the 1^{st} metal line or the 2^{nd} metal line are a single continuum structure without a connection surface, interface or junction therebetween.

6. The semiconductor device of claim 3, wherein the 1^{st} metal line, the 2^{nd} metal line, and the via structure each comprise ruthenium (Ru).

7. The semiconductor device of claim 1, further comprising a 1^{st} via structure on the 1^{st} metal line and a 2^{nd} via structure on the 2^{nd} metal line,
wherein the 1^{st} metal line is connected to the transistor through the 1^{st} via structure, and the 2^{nd} metal line is connected to the storage through the 2^{nd} via structure.

8. The semiconductor device of claim 7, wherein based on a voltage applied to at least one of the 1^{st} via structure or the 2^{nd} via structure, at least one of the 1^{st} via structure or the 2^{nd} via structure is configured to generate current leakage into the isolation structure and the 1^{st} via structure and the 2^{nd} via structure are configured to be electrically connected through the isolation structure.

9. The semiconductor device of claim 7, wherein the 1^{st} metal line and the 1^{st} via structure are a single continuum structure without a connection surface, interface or junction therebetween, and
wherein the 2^{nd} metal line and the 2^{nd} via structure are another single continuum structure without a connection surface, interface or junction therebetween.

10. The semiconductor device of claim 7, wherein the 1^{st} metal line, the 2^{nd} metal line, the 1^{st} via structure and the 2^{nd} via structure each comprise ruthenium (Ru).

11. The semiconductor device of claim 1, wherein the isolation structure comprises a dielectric material.

12. The semiconductor device of claim 1, wherein the 1^{st} metal line and the 2^{nd} metal line extend in a 1^{st} direction and are arranged in a 2^{nd} direction intersecting the 1^{st} direction, and
wherein the isolation structure is above the air gap in a 3^{rd} direction intersecting the 1^{st} direction and the 2^{nd} direction.

13. The semiconductor device of claim 12, further comprising a via structure on the 1^{st} metal line or the 2^{nd} metal line,
wherein, based on the via structure being on the 1^{st} metal line, the 1^{st} metal line is connected to the transistor through the via structure, and
wherein, based on the via structure being on the 2^{nd} metal line, the 2^{nd} metal line is connected to the storage through the via structure.

14. A semiconductor device comprising:
a 1^{st} metal line;
a 2^{nd} metal line adjacent to the 1^{st} metal line;
an air gap between the 1^{st} metal line and the 2^{nd} metal line; and
an isolation structure adjacent to the air gap, the isolation structure comprising an isolation material,
wherein the 1^{st} metal line and the 2^{nd} metal line are configured to be electrically connected through the isolation structure based on a voltage applied to at least one of the 1^{st} metal line or the 2^{nd} metal line.

15. The semiconductor device of claim 14, wherein based on the voltage applied to the at least one of the 1^{st} metal line or the 2^{nd} metal line, the at least one of the 1^{st} metal line or the 2^{nd} metal line is configured to generate current leakage into the isolation structure.

16. The semiconductor device of claim 14, further comprising a via structure on at least one of the 1^{st} metal line or the 2^{nd} metal line,
wherein, based on the voltage applied to the at least one of the 1^{st} metal line or the 2^{nd} metal line through the via structure, the via structure or the at least one of the 1^{st} metal line or the 2^{nd} metal line is configured to generate current leakage into the isolation structure.

17. A semiconductor device comprising:
a transistor;
a storage; and
an interconnect structure connected to the transistor and the storage, the interconnect structure comprising:
a plurality of 1^{st} metal lines in a 1^{st} area of the interconnect structure;
an air gap between two 1^{st} metal lines adjacent to each other among the plurality of 1^{st} metal lines;
a plurality of 2^{nd} metal lines in a 2^{nd} area of the interconnect structure; and
an isolation structure between two 2^{nd} metal lines adjacent to each other among the plurality of 2^{nd} metal lines,
wherein a 2^{nd} metal line among the two 2^{nd} metal lines has a greater width than a 1^{st} metal line among the two 1^{st} metal lines.

18. The semiconductor device of claim 17, wherein a width of the 2^{nd} metal line is equal to a sum width of at least one 1^{st} metal line and the air gap.

19. The semiconductor device of claim 18, further comprising a via structure on at least one of the two 2^{nd} metal lines,
wherein the via structure and the at least one of the two 2^{nd} metal lines are a single continuum structure without a connection surface, interface or junction therebetween.

20. The semiconductor device of claim 17, wherein the plurality of 1^{st} metal lines and the plurality of 2^{nd} metal lines each comprise ruthenium (Ru).
